(19) United States
(12) Patent Application Publication
(10) Pub. No.: US 2006/0057777 A1
(43) Pub. Date: Mar. 16, 2006

(54) Separating die on a substrate to reduce backside chipping

(76) Inventors: William Christopher Howell, Beaverton, OR (US); Dean Lee Monthei, Beaverton, OR (US)

Correspondence Address: Joseph A. Pugh;TriQuint Semiconductor, Inc., 2300 NE Brookwood Parkway, Hillsboro, OR, 97124, US

(21) Appl. No.: 10/940,306

(22) Filed: Sep. 14, 2004

(51) Int. Cl. H01L 21/78

(52) U.S. Cl. 438/113; 438/460

(57) ABSTRACT

A method of separating die on a substrate to reduce backside chipping. Two or more microelectronic components are created on a first side of a substrate, wherein a space exists between adjacent components. A trench is created in the other side of the substrate, wherein the location of the trench coincides with a location of the space between components on the first side of the substrate, and wherein the trench has a depth less than the thickness of the substrate. The substrate material starting at the surface of the first side in the space between the components is removed until reaching at least the trench, to separate the substrate into two or more pieces.

### TECHNICAL FIELD

Embodiments of the invention are generally related to the field of semiconductor processing, and, in particular, to separating die on a substrate to reduce backside chipping.

### BACKGROUND

In the manufacture of microelectronic components, such as, but not limited to, a power amplifier, a low-noise amplifier or a switch, multiple components can be created on a semiconductor substrate. One example of a microelectronic component is semiconductor component or integrated circuit. A semiconductor component created on a substrate is commonly referred to as a die. A substrate is processed on the top, also known as the “front side,” and on the bottom, also known as the “backside,” to create die.

Once multiple die are created on a substrate, the substrate is separated into pieces that contain individual die, which are used in the manufacture of products such as, but not limited to, cellular telephones. Separation of a substrate into individual die may be accomplished by sawing completely through a substrate. For example, once the die are created, a saw is used to cut in the rows between adjacent die, commonly referred to as saw streets, each cut passing through the substrate until it is separated into individual die.

Sawing a substrate for die separation commonly leads to chipping at the edges of the saw cuts on the backside of the die, commonly referred to as “backside chipping.” Backside chipping reduces the mechanical strength at the edge of the die and can cause problems with subsequent assembly operations.

A variety of factors may contribute to backside chipping, among which are the brittleness and the thickness of the substrate. Saw parameters such as blade feed rate may also contribute to backside chipping. In addition, the act of driving a saw blade through the backside of the substrate also contributes to backside chipping.

One way to minimize backside chipping is to reduce saw speeds. However, this can increase saw process time, which can reduce saw capacity and increase production cost. Another way to minimize backside chipping is to prevent a saw blade from penetrating through the substrate and exiting the backside. For example, certain processes involve using a saw blade to penetrate only part of the way through the substrate. With these processes, final die separation is achieved by grinding down the backside of the substrate until the substrate separates into individual die. However, these types of processes can be time consuming.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a flow chart illustrating one embodiment of a method of separating die on a substrate to reduce backside chipping.

FIG. 2 illustrates a cross-section of a substrate having die separated in accordance with one embodiment of the invention.

### DETAILED DESCRIPTION

A method of separating die on a substrate to reduce backside chipping is described. In the following description, for purposes of explanation, numerous specific details are set forth. It will be apparent, however, to one skilled in the art that embodiments of the invention can be practiced without these specific details. In other instances, structures and devices are shown in block diagram form in order to avoid obscuring the understanding of this description.

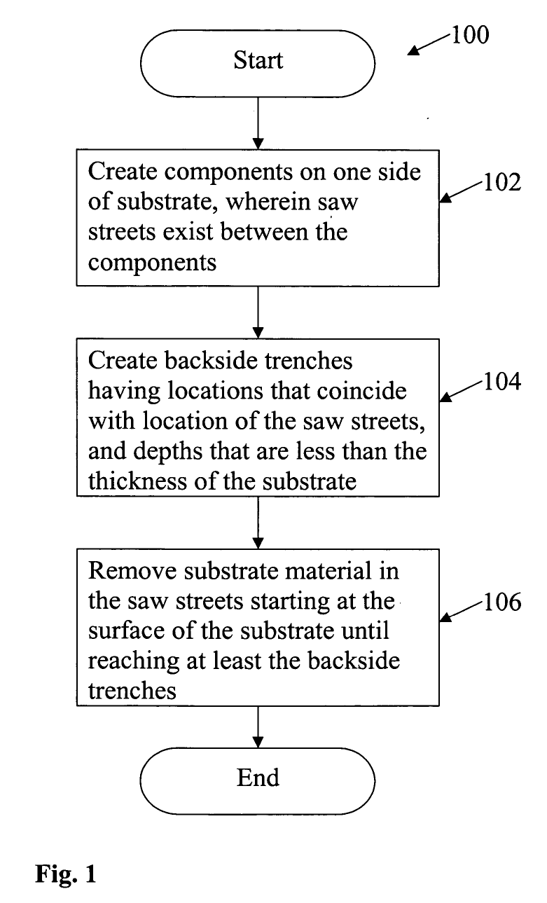

FIG. 1 is a flow chart illustrating one embodiment of a method of separating individual die on a substrate. At 102 of method 100, two or more components are created on one side of a substrate, wherein space exists between adjacent components. As used herein, “component” refers to either any microelectronic component in general, including any semiconductor component. For purposes of illustration and ease of explanation, the term “die” will be used to mean any type of component created on the surface of a substrate. For purposes of illustration and ease of explanation, the term “saw street” will be used to refer to the space between adjacent die on the surface of a substrate.

A substrate that contains die may be referred to as a semiconductor wafer, or simply wafer. As used herein, “substrate” will be used to mean either a substrate or a wafer. In addition, a substrate may include one or more layers of metal added onto the front side. As used herein, “substrate” will be used to mean a substrate that does not have one or more layers of metal added onto the front side, as well as a substrate that includes one or more layers of metal added onto the front side.

Although embodiments of the invention will be described in terms of creating multiple saw streets, embodiments of the invention may also be practiced in which only one saw street is created. In one embodiment, the substrate comprises a gallium arsenide substrate. However, embodiments of the invention are not limited to gallium arsenide substrates. Other types of substrates may be used, including, but not limited to, silicon substrates.

At 104, trenches are created in the other side of the substrate, such that the locations of the trenches coincide with the locations of the saw streets between the die, and the depths of the trenches are less than the thickness of the substrate. For purposes of illustration and ease of discussion, the side of the substrate on which the die are created will be referred to as the front side of the substrate, while the side on which the trenches are created will be referred to as the backside.

In one embodiment, the trenches on the backside of the substrate, hereinafter referred to as “backside trenches,” are created using any etching process known in the art. A reason for creating backside trenches using an etching process is to take advantage of any backside processing that uses the etching process. For example, an etching process may be used on the backside to create a hole, commonly referred to as a substrate via, from the bottom of the substrate through the substrate.

Alignment of the backside trenches to coincide with the saw streets can be achieved using optical alignment techniques, such as, but not limited to, a photolithographic alignment technique. For example, a pattern for the saw streets can be created. The saw street pattern can be translated to an etch mask, for example, so that the backside trenches coincide with the saw streets. When the etching process is used to create a substrate via, for example, the etching process can also be used to create the backside trenches. Consequently, the backside trenches can be created with little or no additional manufacturing cost.

Creation of backside trenches is not limited to using an etching process. In other embodiments, the backside trenches may be cut using, but not limited to, a laser. In addition, the idea of creating backside trenches with little or no additional manufacturing cost applies to any process in which creation of the backside trenches can be incorporated as part of backside processing.

At 106, the substrate material in the saw streets is removed starting at the surface of the substrate until reaching at least the backside trench, to separate the substrate into individual die. In one embodiment, a saw is used to cut in the locations of the saw streets at least deep enough to cut through the material between the surface of substrate and the backside trenches. In an alternative embodiment, a laser is used to cut through at least the material between the surface of the substrate and the backside trenches. In addition, the material between the surface of the substrate and the backside trenches may be removed starting from the backside trenches.

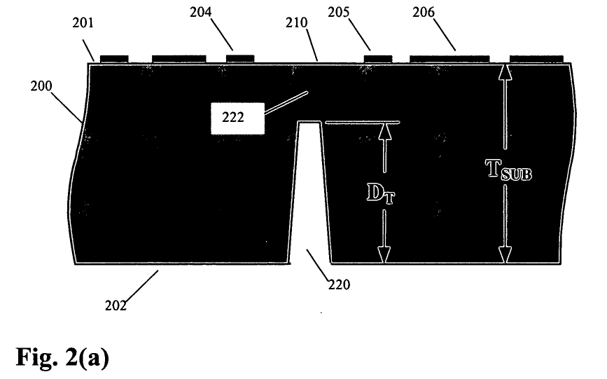

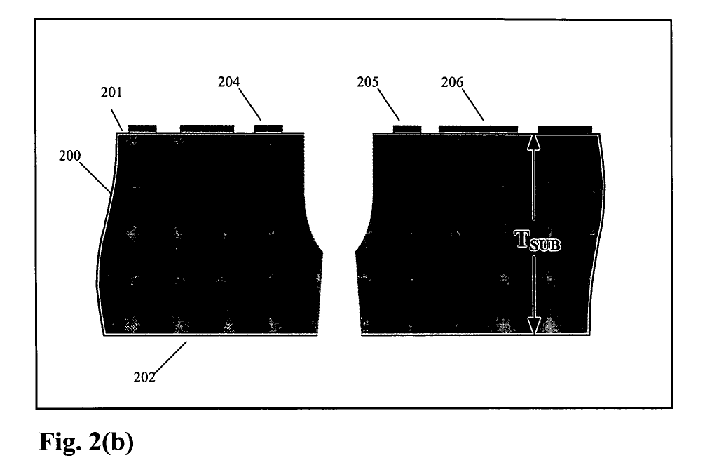

FIG. 2 illustrates a cross-section of a substrate having die separated to reduce backside chipping in accordance with one embodiment of the invention. Substrate 200 has a front side 201 and a backside 202. Front side 201 includes individual die 204, 205 and 206, for example. In FIG. 2(a), saw street 210 exists between die 204 and die 205.

A trench 220 is created on backside 202. The location of trench 220 on backside 202 coincides with the location of saw street 210. The depth D_{T} of trench 220 is less than T_{SUB}, the thickness of the substrate, which allows substrate material 222 to remain between trench 220 and the surface of substrate 200 at saw street 210.

To separate the portion of substrate 200 that includes die 204 from the portion of substrate 200 that includes die 205, remaining material 222 is removed, as shown in FIG. 2(b). Repeating this technique in the spaces between other adjacent die on substrate 200, e.g., die 205 and 206, enables the individual die to be separated.

The technique described above reduces backside chipping caused, at least in part, by a saw pushing through the backside of a substrate. Reduced backside chipping leads to increased mechanical strength at the edge of a die, as compared to a die that has backside chipping at its edges, thereby reducing potential problems with subsequent assembly operations. Moreover, when a saw is used to remove the material remaining between the surface of the substrate and the backside trenches, the speed of the saw need not be reduced because of backside chipping since the saw is not pushing through the backside of the substrate. This can reduce saw process time, thereby increasing saw capacity and reducing production cost. When a laser is used to remove the material remaining between the surface of the substrate and the backside trenches, cut time may reduced even further since typical laser cut speeds can be faster than those of saws.

Reference in the foregoing specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

In the foregoing specification, the invention has been described with reference to specific embodiments thereof. It will, however, be evident that various modifications and changes can be made thereto without departing from the broader spirit and scope of the invention. The specification and drawings are, accordingly, are to be regarded in an illustrative rather than a restrictive sense.

What is claimed is:

1. A method, comprising:
creating two or more components on a first side of a substrate, wherein a space exists between adjacent components;
creating a trench in a second side of the substrate, wherein a location of the trench coincides with a location of the space, and wherein the trench has a depth less than a thickness of the substrate; and
removing substrate material starting at the surface of the first side in the space between the components until reaching at least the trench, to separate the substrate into two or more pieces.

2. The method of claim 1, wherein creating the trench comprises cutting the trench using an etching process.

3. The method of claim 1, wherein creating the trench comprises cutting the trench using a laser.

4. The method of claim 1, wherein creating the trench comprises:
cutting slots in a mask, wherein the slots correspond to the locations of the space between the components;
laying the mask on the second side; and
removing substrate material on the second side at locations within the slots.

5. The method of claim 1, wherein the substrate comprises a gallium arsenide substrate.

6. The method of claim 1, wherein the substrate comprises a silicon substrate.

7. The method of claim 1, wherein removing the substrate material starting at the surface of the first side until reaching the trench comprises sawing in the space to a depth sufficient to reach the trench.

8. The method of claim 1, wherein removing the substrate material starting at the surface of the first side until reaching at least the trench comprises using a laser to remove the substrate material until reaching at least the trench.

9. The method of claim 1, wherein the substrate includes a deposited layer.

10. A method, comprising:
creating die on a front side of substrate, wherein a saw street exists between the die;
etching a trench on a backside of the substrate, wherein a location of the trench coincides with a location of the saw street, and wherein the trench is cut to a depth that allows material to remain between the trench and the surface of the front side surface of the substrate; and
cutting into the saw street from the surface of the front side of the substrate down to at least the trench.

11. The method of claim 10, wherein cutting into the saw street comprises cutting into the saw street using a saw.

12. The method of claim 10, wherein cutting into the saw street comprises cutting into the saw street using a laser.

13. The method of claim 10, wherein the substrate includes a deposited layer.
